(19) United States
(12) Patent Application Publication
(10) Pub. No.: US 2002/0094597 A1
(43) Pub. Date: Jul. 18, 2002

(54) Quantum dot infrared photodetector and method for fabricating the same

(75) Inventors: Shih-Yen Lin, Hsinchu (TW); Shiang-Feng Tang, Taichung (TW); Si-Chen Lee, Taipei (TW); Chieh-Hsiung Kuan, Taipei (TW)

Correspondence Address: Skjerven, Morrill Macpherson LLP, 25 Metro Drive, Suite 700, San Jose, CA, 95110, US

(73) Assignee: National Science Council, Taipei (TW)

(21) Appl. No.: 09/846,173

(22) Filed: Apr. 30, 2001

(30) Foreign Application Priority Data
Jan. 15, 2001 (TW) 90100850

(51) Int. Cl. H01L 21/00; H01L 21/28; H01L 21/3205

(52) U.S. Cl. 438/57; 438/604

(57) ABSTRACT

A method for fabricating a quantum dot infrared photodetector by using molecular beam epitaxy is provided. The method includes steps of growing a first gallium arsenide layer as a buffer layer on a gallium arsenide substrate, growing a first undoped aluminum gallium arsenide layer as a blocking layer on the first gallium arsenide layer, growing a quantum dot structure layer on the first undoped aluminum gallium arsenide layer at a specific temperature, and growing a second gallium arsenide layer as a contact layer on the quantum dot structure layer.

### FIELD OF THE INVENTION

The present invention relates to a quantum dot infrared photodetector and a method for fabricating the same, and more particularly to a quantum infrared photodetector operated at high temperature and having high detectivity.

### BACKGROUND OF THE INVENTION

Quantum dots have good electrical and optical characteristics owing to the three-dimensional quantum confinement effect. There are four traditional methods for fabricating quantum dots, for example etching and photolithography process, chemical synthesis, steam plating and molecular beam epitaxy.

However, the etching and photolithography process is low efficient and needs high fabricating cost. Both the chemical synthesis and the steam plating need a long time. The quantum dots formed by chemical synthesis or steam plating are not easily fixed on semiconductors.

The quantum dots formed by molecular beam epitaxy could be controlled precisely to grow on a molecular layer. The molecular beam epitaxy could be used in producing large areas (greater than 4 inch²) of quantum dots. In addition, the molecular beam epitaxy is beneficial for growing complicated structures.

However, a traditional quantum well infrared photodetector formed by molecular beam epitaxy has selectivity for vibration direction of incident light. Because of the short life time of electron-hole pairs, the operation temperature of the quantum well infrared photodetector is usually below 100K.

In order to overcome the foresaid drawbacks in the prior art, the present invention provides a method for fabricating a quantum dot infrared photodetector by molecular beam epitaxy. The quantum dot infrared photodetector provided in the present invention has high detectivity and could be operated at high temperature.

### SUMMARY OF THE INVENTION

It is therefore an object of the present invention to provide a method for fabricating a quantum dot infrared photodetector by using molecular beam epitaxy.

In accordance with the present invention, the method for fabricating a quantum dot infrared photodetector by using molecular beam epitaxy includes steps of a) growing a first gallium arsenide layer as a buffer layer on a gallium arsenide substrate, b)growing a first undoped aluminum gallium arsenide layer as a blocking layer on the first gallium arsenide layer, c) growing a quantum dot structure layer on the first undoped aluminum gallium arsenide layer at a specific temperature, and d) growing a second gallium arsenide layer as a contact layer on the quantum dot structure layer.

Preferably, the first gallium arsenide layer and the second gallium arsenide layer are n-type gallium arsenide layers. The first gallium arsenide layer has a thickness of about 1 μm. The first undoped aluminum gallium arsenide layer has a thickness of about 50 nm. The specific temperature is ranged from 480° C. to 520° C.

In addition, the quantum dot structure layer is formed by multiple layers having n-type indium arsenide quantum dots buried in an undoped gallium arsenide barrier layer. The undoped gallium arsenide barrier layer has a thickness of about 30 nm.

Preferably, the quantum dot structure layer is made of one of silicon/silicon germanium composite and indium gallium arsenide/gallium arsenide composite. The number of the repeated layers is ranged from 3 to 100.

In accordance with the present invention, between the step c) and the step d) the method further includes a step of growing a second undoped gallium arsenide layer as a blocking layer.

Preferably, the second undoped aluminum gallium arsenide layer has a thickness of about 50 nm. The aluminum contents of the first aluminum gallium arsenide layer and the second aluminum gallium arsenide layer are ranged from 10% to 100% by weight, respectively. The second gallium arsenide has a thickness of about 0.5 μm.

It is another object of the present invention to provide a method for fabricating a quantum dot infrared photodetector by using molecular beam epitaxy.

In accordance with the present invention, the method for fabricating a quantum dot infrared photodetector by using molecular beam epitaxy includes steps of a) growing a first gallium arsenide layer as a buffer layer on a gallium arsenide substrate, b) growing a quantum dot structure layer on the gallium arsenide substrate at a specific temperature, c) growing an undoped aluminum gallium arsenide layer as a blocking layer on the quantum dot structure layer, and d) growing a second gallium arsenide layer as a contact layer on the undoped aluminum gallium arsenide layer.

It is another object of the present invention to provide a method for fabricating a quantum dot infrared photodetector by using molecular beam epitaxy.

In accordance with the present invention, the method for fabricating a quantum dot infrared photodetector by using molecular beam epitaxy includes steps of a) growing a first gallium arsenide layer as a buffer layer on a gallium arsenide substrate, b) growing a first undoped aluminum gallium arsenide layer as a blocking layer on the gallium arsenide substrate, c) growing a quantum dot structure layer on the first undoped aluminum gallium arsenide layer at a specific temperature, d) growing a second undoped aluminum gallium arsenide layer as a stop layer on the quantum dot structure layer, and e) growing a second gallium arsenide layer as a contact layer on the second undoped gallium arsenide layer.

It is another object of the present invention to provide a quantum dot infrared photodetector structure.

In accordance with the present invention, the structure includes a gallium arsenide substrate, a first gallium arsenide layer as a first buffer layer formed on the gallium arsenide substrate, a first undoped aluminum gallium arsenide layer as a blocking layer formed on the gallium arsenide layer, a quantum dot structure layer formed on the first undoped aluminum gallium arsenide layer, a second undoped aluminum gallium arsenide layer as a second buffer layer formed on the quantum dot structure layer, and a second gallium arsenide layer as a contact layer formed on the second undoped aluminum gallium arsenide.

Preferably, the first gallium arsenide layer and the second gallium arsenide layer are n-type gallium arsenide layers.

In addition, the quantum dot structure layer is formed by multiple layers including indium arsenide quantum dots formed under an arsenic deficient condition and buried in an undoped gallium arsenide barrier layer.

Preferably, the quantum dot structure layer is made of one of silicon/silicon germanium composite and indium gallium arsenide/gallium arsenide composite. The number of the multiple layers is ranged from 3 to 100. The aluminum contents of the first aluminum gallium arsenide layer and the second aliminum gallium arsenide layer are ranged from 10% to 100% by weight, respectively. The first gallium arsenide layer has a thickness about 1 μm.

The present invention may best be understood through the following descriptions with reference to the accompanying drawings, in which:

### BRIEF DESCRIPTION OF THE DRAWINGS

FIG. 1(a) and (b) are schematic views showing the method for fabricating a quantum dot infrared photodetector by molecular beam epitaxy according to the preferred embodiment of the present invention;

FIG. 2 is a diagram showing the relationship between PI intensity and energy analyzed from the quantum dot infrared photodetector structure provided according to the preferred embodiment of the present invention;

FIG. 3(a) is a diagram showing the relationship between responsivity and wavelength analyzed from the quantum dot infrared photodetector structure provided according to the preferred embodiment of the present invention;

FIG. 3(b) is a diagram showing the relationship between responsivity and wavelength analyzed from the quantum dot infrared photodetector structure provided according to the preferred embodiment of the present invention;

FIG. 3(c) is a diagram showing the relationship between current and voltage analyzed from the quantum dot infrared photodetector structure provided according to the preferred embodiment of the present invention;

FIG. 4 is a diagram showing the relationship between responsivity and wavelength at zero bias and varied temperature analyzed from the quantum dot infrared photodetector structure provided according to the preferred embodiment of the present invention; and

FIG. 5 is a diagram showing the relationship between photovoltaic detectivity and temperature at zero bias analyzed from the quantum dot infrared photodetector structure provided according to the preferred embodiment of the present invention.

### DETAILED DESCRIPTION OF THE PREFERRED EMBODIMENTS

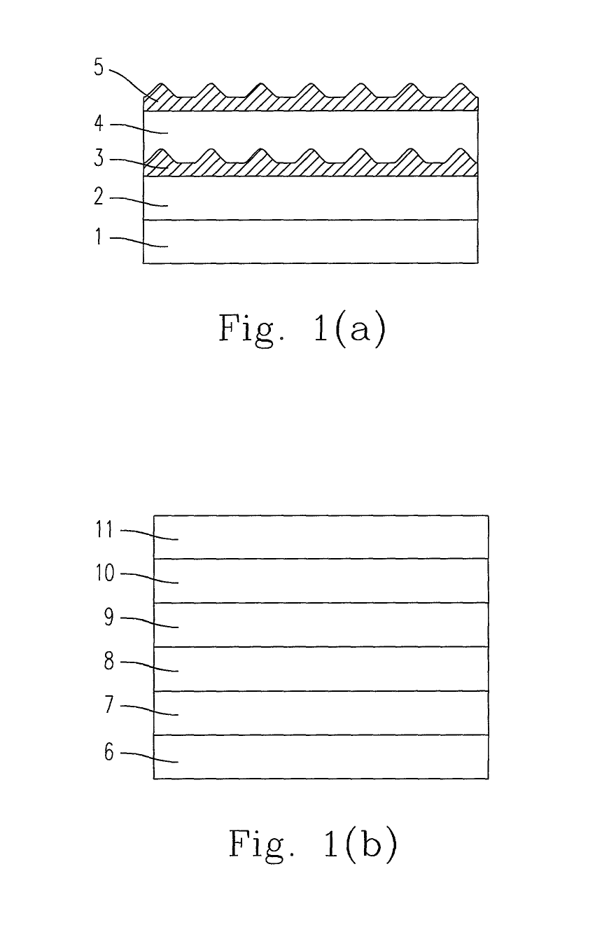

Please refer to FIG. 1(a). A gallium arsenide (GaAs) layer is grown as a buffer layer 2 on a GaAs substrate 1. An indium arsenide (InAs) quantum dot structure layer 3 is grown on the buffer layer 2 under arsenic deficient condition. Subsequently, a GaAs layer 4 having a thickness of about 50 nm is grown on the InAs quantum dot structure layer 3, and another InAs quantum dot structure layer 5 is grown thereon.

The foresaid InAs quantum dot structure layer is a mono layer structure. Certainly, an InAs quantum dot structure layer having multiple layers in a quantum dot infrared photodetector could be designed as shown in FIG. 1(b). An n-type gallium arsenide layer having a thickness of about 1 μm is grown as a buffer layer 7 on an undoped gallium arsenide substrate 6. An undoped aluminum gallium arsenide (AlₓGa₁₋ₓAs) layer having a thickness of about 50 nm and a high energy gap is grown as a blocking layer 8 on the buffer layer 7, wherein the aluminum content of the blocking layer 8 is ranged from 10% to 100% by weight.

Subsequently, an undoped GaAs layer having a thickness of about 30 nm is grown as a barrier layer at the temperature ranged from 480° C. to 520° C . Then, n-type InAs quantum dots are grown and buried in the barrier layer. After repeating to grow n-type InAs quantum dots buried in the barrier layer for several times, a quantum dot structure layer 9 having multiple stacked layers is formed. Furthermore, an undoped AlₓGa₁₋ₓAs layer having a thickness of about 50 nm and high energy gap is grown as a stop layer 10 on the quantum dot structure layer 9. An n-type GaAs layer is grown on the stop layer 10 as a contact layer 11.

The quantum dots excited from the electrons in the structure formed according to FIG. 1(b) are accumulated between the blocking layer 8 and the blocking layer 10. The life time of the electrons is substantially increased because the electrons are stopped by the barriers around the quantum dots and hardly back to the quantum dots. Hence, the electrons are accumulated a lot on the conductive belt, and the current is substantially increased after exposure to light. Therefore, the quantum dot infrared photodetector structure could be operated at the high temperature.

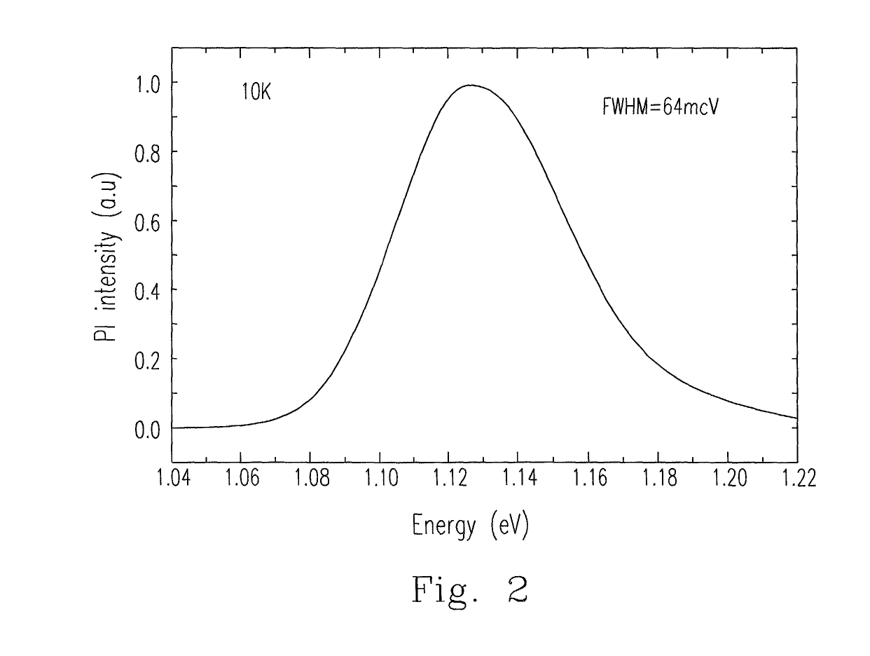

According to the experiment result shown in FIG. 2, the InAs quantum dots grown on the GaAs substrate are uniform-distributed under arsenic deficient condition.

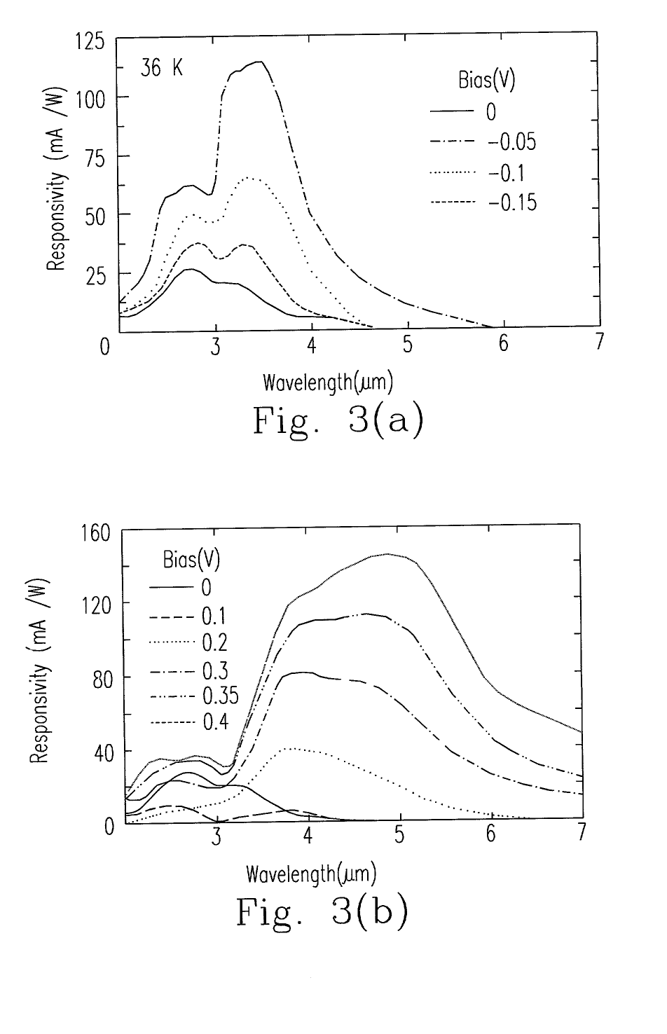

According to the experiment results shown in FIGS. 3(a) to (c), the background-limited-performance (BLIP) temperature of the quantum dot infrared photodetector provided by the present invention is raised close to room temperature, e.g. 250K, and the quantum dot infrared photodetector is PC-PV type infrared photodetector at the low temperature.

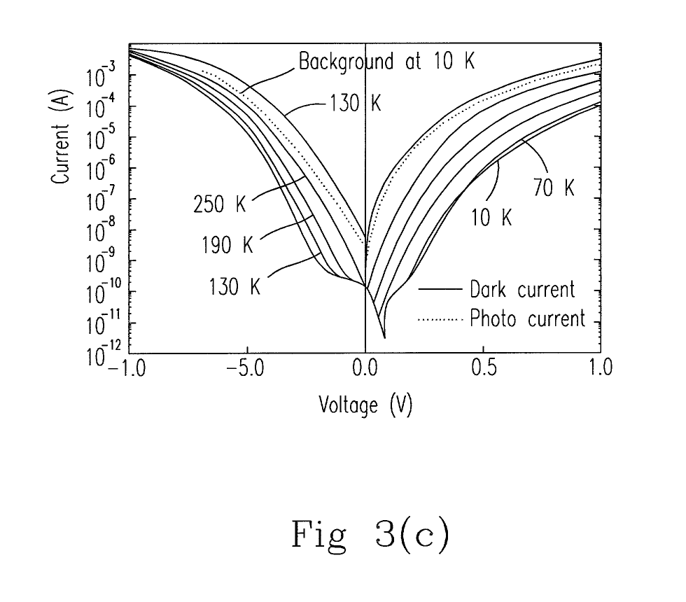

According to the experiment result shown in FIG. 4, the life time of the electrons caught back to the quantum dots is still higher than the initial life time of the electrons. The AlₓGa₁₋ₓAs in the structure could not only stop the dark current, but also enhance the photoconductive reactions.

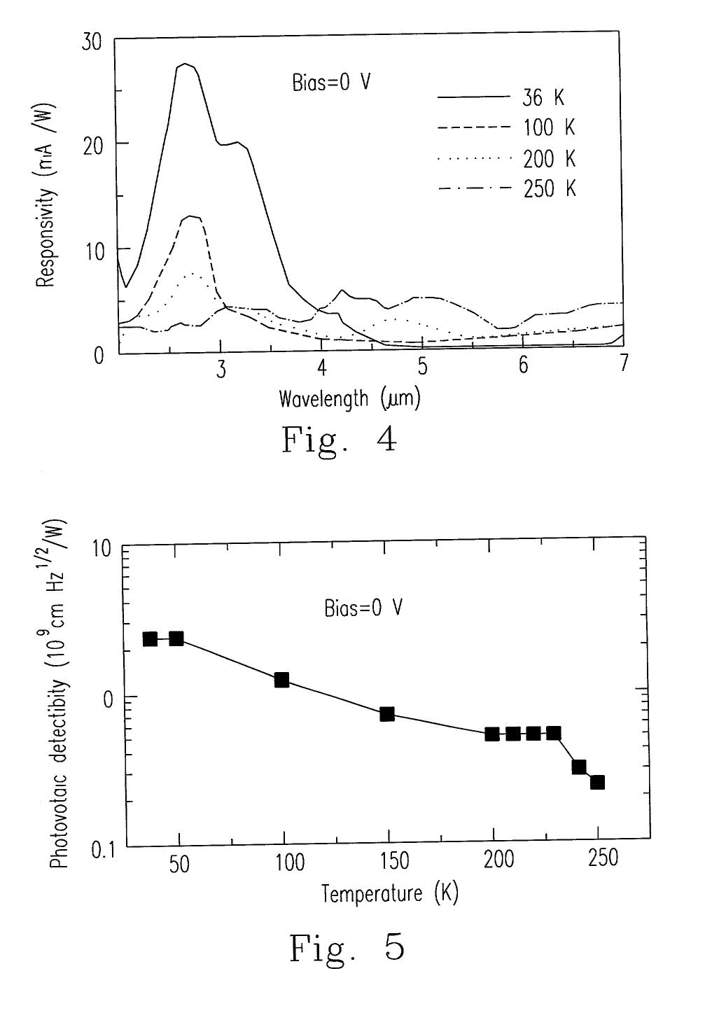

According to the experiment result shown in FIG. 5, the specific peak detectivity of the quantum dot infrared photodetector is 2.4×10⁸ cmHz^{½}/W.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A method for fabricating a quantum dot infrared photodetector by using molecular beam epitaxy, comprising steps of:
a) growing a first gallium arsenide layer as a buffer layer on a gallium arsenide substrate;
b) growing a first undoped aluminum gallium arsenide layer as a blocking layer on said first gallium arsenide layer;
c) growing a quantum dot structure layer on said first undoped aluminum gallium arsenide layer at a specific temperature; and
d) growing a second gallium arsenide layer as a contact layer on said quantum dot structure layer.

2. The method according to claim 1, wherein said first gallium arsenide layer and said second gallium arsenide layer are n-type gallium arsenide layers.

3. The method according to claim 1, wherein said first gallium arsenide layer has a thickness about 1 μm.

4. The method according to claim 1, wherein said first undoped aluminum gallium arsenide layer has a thickness about 50 nm.

5. The method according to claim 1, wherein said specific temperature is ranged from 480° C. to 520° C.

6. The method according to claim 1, wherein said quantum dot structure layer is formed by multiple layers comprising n-type indium arsenide quantum dots buried in an undoped gallium arsenide barrier layer.

7. The method according to claim 6, wherein said undoped gallium arsenide barrier layer has a thickness about 30 nm.

8. The method according to claim 6, wherein said quantum dot structure layer is made of one of silicon/silicon germanium composite and indium gallium arsenide/gallium arsenide composite.

9. The method according to claim 6, wherein the number of said multiple layers is ranged from 3 to 100.

10. The method according to claim 1, between said step c) and said step d) said method further comprising a step of growing a second undoped aluminum gallium arsenide layer as a blocking layer.

11. The method according to claim 11, wherein said second undoped aluminum gallium arsenide layer has a thickness of about 50 nm.

12. The method according to claim 11, wherein aluminum contents of said first aluminum gallium arsenide layer and said second aluminum gallium arsenide layer are ranged from 10% to 100% by weight, respectively.

13. The method according to claim 1, wherein said second gallium arsenide has a thickness of about 0.5 μm.

14. A method for fabricating a quantum dot infrared photodetector by using molecular beam epitaxy, comprising steps of:
a) growing a first gallium arsenide layer as a buffer layer on a gallium arsenide substrate;
b) growing a quantum dot structure layer on said gallium arsenide substrate at a specific temperature;
c) growing an undoped aluminum gallium arsenide layer as a blocking layer on said quantum dot structure layer; and
d) growing a second gallium arsenide layer as a contact layer on said undoped aluminum gallium arsenide layer.

15. A method for fabricating a quantum dot infrared photodetector by using molecular beam epitaxy, comprising steps of:
a) growing a first gallium arsenide layer as a buffer layer on a gallium arsenide substrate;
b) growing a first undoped aluminum gallium arsenide layer on said gallium arsenide substrate;
c) growing a quantum dot structure layer on said first undoped aluminum gallium arsenide layer at a specific temperature;
d) growing a second undoped aluminum gallium arsenide layer as a blocking layer on said quantum dot structure layer; and
e) growing a second gallium arsenide layer as a contact layer on said second undoped gallium arsenide layer.

16. A quantum dot infrared photodetector structure comprising:
a gallium arsenide substrate;
a first gallium arsenide layer as a first buffer layer formed on said gallium arsenide substrate;
a first undoped aluminum gallium arsenide layer as a blocking layer formed on said gallium arsenide layer;
a quantum dot structure layer formed on said first undoped aluminum gallium arsenide layer;
a second undoped aluminum gallium arsenide layer as a second buffer layer formed on said quantum dot structure layer; and
a second gallium arsenide layer as a contact layer formed on said second undoped aluminum gallium arsenide.

17. The structure according to claim 16, wherein said first gallium arsenide layer and said second gallium arsenide layer are n-type gallium arsenide layers.

18. The structure according to claim 16, wherein said quantum dot structure layer is formed by multiple layers comprising indium arsenide quantum dots formed under an arsenic deficient condition and buried in an undoped gallium arsenide barrier layer.

19. The structure according to claim 18, wherein said quantum dot structure layer is made of one of silicon/silicon germanium composite and indium gallium arsenide/gallium arsenide composite.

20. The structure according to claim 18, wherein the number of said multiple layers is ranged from 3 to 100.

21. The structure according to claim 16, wherein aluminum contents of said first aluminum gallium arsenide layer and said second aliminum gallium arsenide layer are ranged from 10% to 100% by weight, respectively.

22. The structure according to claim 16, wherein said first gallium arsenide layer has a thickness of about 1 μm.
